(19) United States
(12) Patent Application Publication
(10) Pub. No.: US 2025/0385091 A1
(43) Pub. Date: Dec. 18, 2025

(54) SEMICONDUCTOR DEVICE AND METHOD FOR MANUFACTURING THE SAME USING MULTILAYER MASK

(71) Applicant: NANYA TECHNOLOGY CORPORATION, NEW TAIPEI CITY (TW)

(72) Inventor: YA-CHIN LIN, NEW TAIPEI CITY (TW)

(21) Appl. No.: 18/765,542

(22) Filed: Jul. 8, 2024

Related U.S. Application Data
(62) Division of application No. 18/742,162, filed on Jun. 13, 2024.

(51) Int. Cl. H01L 21/033; H01L 23/14

(52) U.S. Cl. CPC H01L 21/0332; H01L 23/147; H10D 1/042; H10D 1/714; H10D 1/716

(57) ABSTRACT

A semiconductor device and a method of manufacturing a semiconductor device are provided. The semiconductor device includes a substrate, a plurality of lower electrodes disposed on the substrate, and at least one support structure pattern supporting the plurality of lower electrodes. The at least one support structure pattern define an open region having a first dimension along a first direction and a second dimension along a second direction. A ratio of the second dimension to the first dimension is greater than 1.5.

### CROSS-REFERENCE TO RELATED APPLICATION

This application is a divisional application of U.S. Non-Provisional Application No. 18/742,162 filed June 13, 2024, which is incorporated herein by reference in its entirety.

### TECHNICAL FIELD

The present disclosure relates to a semiconductor device and a method for manufacturing a semiconductor device, and more particularly, to a method for manufacturing a semiconductor device using a multilayer mask.

### DISCUSSION OF THE BACKGROUND

In a semiconductor device like a dynamic random access memory (DRAM), a support structure pattern can be used to prevent the lower electrode of a capacitor from collapsing or breaking. The integration density of semiconductor devices has recently increased due to the rapid development of miniaturized semiconductor processing technology. Consequently, a unit cell area has been significantly reduced, and an aspect ratio of a lower electrode of a capacitor has been substantially increased.

However, as a result of the increased aspect ratio, a typical problem is that the opening of the support structure pattern is difficult to control, potentially increasing the difficulty of forming the dielectric material of the capacitor in subsequent operations. To maintain or increase capacitance, the opening of the support structure pattern is a limiting factor that must be addressed to achieve further improvements in semiconductor device integration.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a plurality of lower electrodes disposed on the substrate, and at least one support structure pattern supporting the plurality of lower electrodes. The at least one support structure pattern define an open region having a first dimension along a first direction and a second dimension along a second direction. A ratio of the second dimension to the first dimension is greater than 1.5.

Another aspect of the present disclosure provides a method of manufacturing a semiconductor device. The method includes forming an insulating layer on a substrate, forming a plurality of lower electrodes in the insulating layer; forming a multilayer mask on the insulating layer, and etching the insulating layer with the multilayer mask.

Another aspect of the present disclosure provides a method of manufacturing a semiconductor device. The method includes forming a plurality of lower electrodes, forming a support structure pattern supporting the plurality of lower electrodes, forming a multilayer mask on the support structure pattern, and forming an open region having an ellipse shape with the multilayer mask.

By using a multilayer mask to form the open region, a ratio of the major axis to the minor axis of the elliptical shape of the open region can be greater than 1.5. The capacitor dielectric layer may be completely formed in the open region. Therefore, the performance and operational reliability of the semiconductor device can be improved.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a schematic plan view of a semiconductor device in accordance with some embodiments of the present disclosure.

FIG. 1B is a schematic cross-sectional view illustrating the semiconductor device taken along a B-B’ line shown in FIG. 1A.

FIG. 2 is a schematic cross-sectional view illustrating one or more stages of a method of manufacturing a semiconductor device in accordance with some embodiments of the present disclosure.

FIG. 3A is a schematic plan view illustrating one or more stages of a method of manufacturing a semiconductor device in accordance with some embodiments of the present disclosure.

FIG. 3B is a schematic cross-sectional view illustrating the semiconductor device taken along a B-B’ line shown in FIG. 3A.

FIG. 4 is a schematic cross-sectional view illustrating one or more stages of a method of manufacturing a semiconductor device in accordance with some embodiments of the present disclosure.

FIG. 5 is a schematic cross-sectional view illustrating one or more stages of a method of manufacturing a semiconductor device in accordance with some embodiments of the present disclosure.

FIG. 6 is a schematic cross-sectional view illustrating one or more stages of a method of manufacturing a semiconductor device in accordance with some embodiments of the present disclosure.

FIG. 7 is a schematic cross-sectional view illustrating one or more stages of a method of manufacturing a semiconductor device in accordance with some embodiments of the present disclosure.

FIG. 8 is a schematic cross-sectional view illustrating one or more stages of a method of manufacturing a semiconductor device in accordance with some embodiments of the present disclosure.

FIG. 9 is a schematic cross-sectional view illustrating one or more stages of a method of manufacturing a semiconductor device in accordance with some embodiments of the present disclosure.

FIG. 10A is a schematic plan view illustrating one or more stages of a method of manufacturing a semiconductor device in accordance with some embodiments of the present disclosure.

FIG. 10B is a schematic cross-sectional view illustrating the semiconductor device taken along a B-B’ line shown in FIG. 10A.

FIG. 11 is a schematic cross-sectional view illustrating one or more stages of a method of manufacturing a semiconductor device in accordance with some embodiments of the present disclosure.

FIG. 12 is a schematic cross-sectional view illustrating one or more stages of a method of manufacturing a semiconductor device in accordance with some embodiments of the present disclosure.

FIG. 13 is a schematic cross-sectional view illustrating one or more stages of a method of manufacturing a semiconductor device in accordance with some embodiments of the present disclosure.

FIG. 14 is a schematic cross-sectional view illustrating one or more stages of a method of manufacturing a semiconductor device in accordance with some embodiments of the present disclosure.

FIG. 15 is a schematic cross-sectional view illustrating one or more stages of a method of manufacturing a semiconductor device in accordance with some embodiments of the present disclosure.

FIG. 16 is a schematic cross-sectional view illustrating one or more stages of a method of manufacturing a semiconductor device in accordance with some embodiments of the present disclosure.

FIG. 17 is a schematic cross-sectional view illustrating one or more stages of a method of manufacturing a semiconductor device in accordance with some embodiments of the present disclosure.

FIG. 18 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

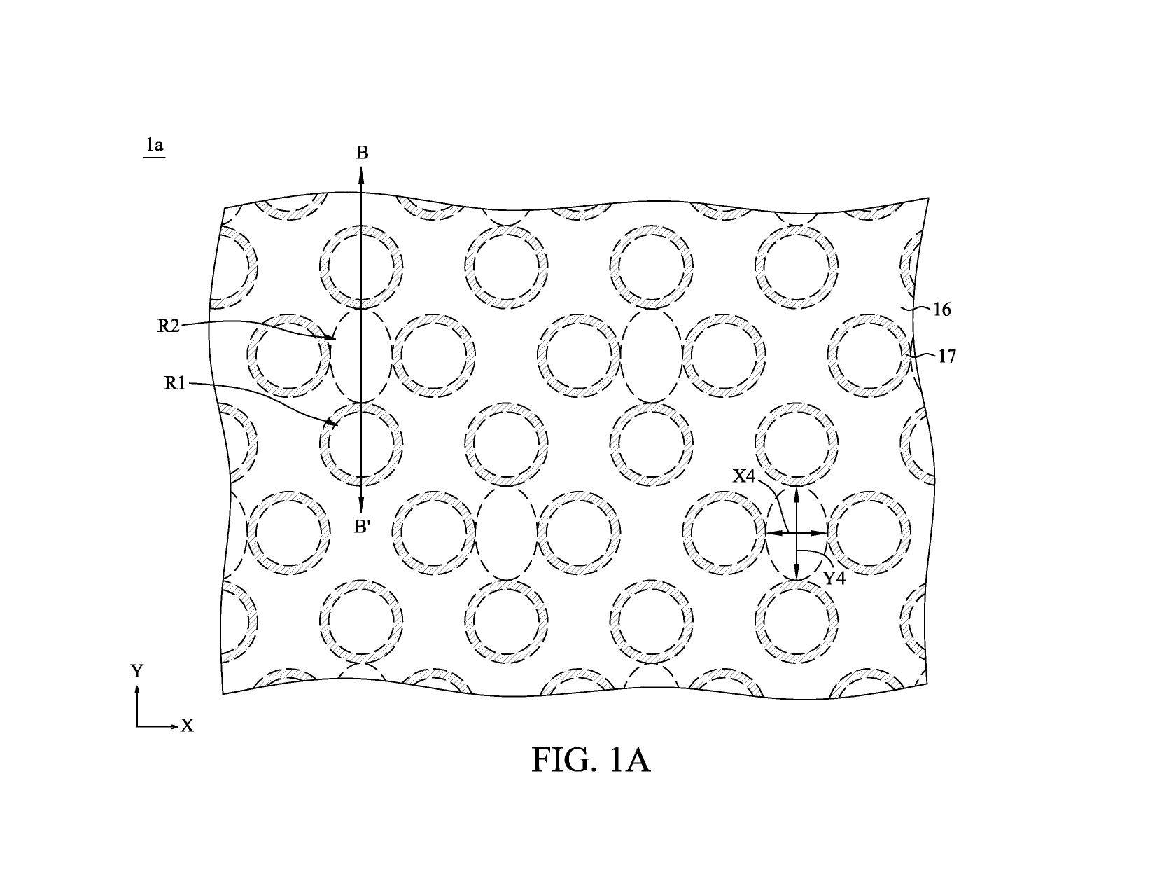

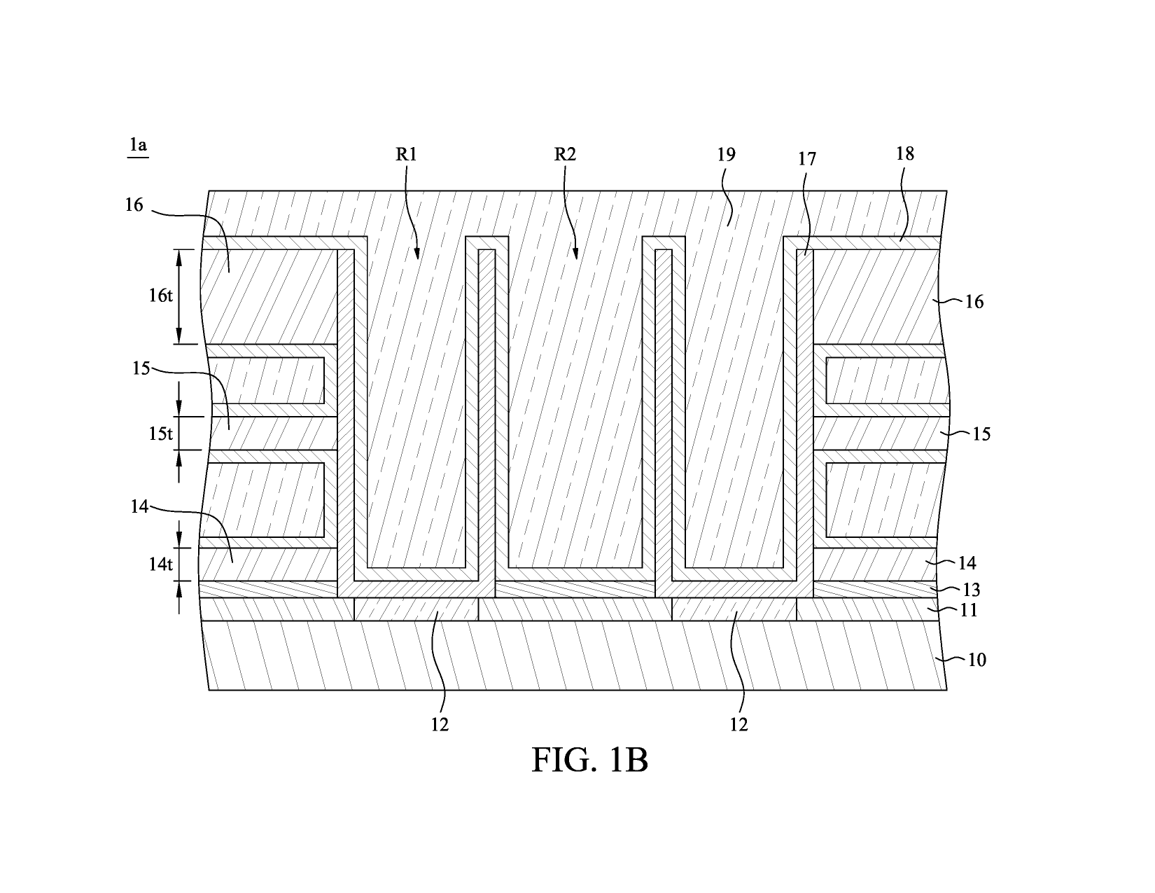

FIG. 1A is a schematic plan view of a semiconductor device 1a in accordance with some embodiments of the present disclosure. In some embodiments, the semiconductor device 1a may be disposed adjacent to a circuit. For example, the semiconductor device 1a may be disposed adjacent to a memory device such as a dynamic random access memory (DRAM) device or the like.

FIG. 1B is a schematic cross-sectional view illustrating the semiconductor device 1a taken along a B-B’ line shown in FIG. 1A. A capacitor dielectric layer 18 and an upper electrode 19 are omitted from FIG. 1A to simplify the explanation and maintain conciseness.

Referring to FIG. 1A and FIG. 1B, the semiconductor device 1a may include a substrate 10, an interlayer insulating layer 11, a plurality of contact plugs 12, an etch stop layer 13, support structure patterns 14, 15, 16, a plurality of lower electrodes 17, a capacitor dielectric layer 18, and an upper electrode 19.

The substrate 10 may include a semiconductor substrate. In some embodiments, the semiconductor material of the substrate 10 may include, for example, silicon (Si) (such as monocrystalline silicon, polysilicon, and amorphous silicon), germanium (Ge), gallium (Ga), and indium (In). In some embodiments, the semiconductor material of the substrate 10 may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

Although not illustrated, a plurality of the active regions may be defined by an isolation region on the substrate 10. Word lines and bit lines may be formed on the substrate 10.

The interlayer insulating layer 11 may be formed on the substrate 10. The interlayer insulating layer 11 may include silicon oxide (SiO₂), silicon nitride (SiN), or silicon oxynitride (SiON). The interlayer insulating layer 11 may be a single layer or a multi-layer.

The plurality of contact plugs 12 may be formed in the interlayer insulating layer 11 on the substrate 10. The contact plugs 12 may be connected to a source electrode or a drain electrode of a transistor included in the substrate 10. For example, the contact plug 12 may include a landing pad and a storage node contact. The contact plugs 12 may include a conductive material. The contact plugs 12 may include a doped semiconductor material (e.g., doped silicon), a metal (e.g., tungsten, titanium, and tantalum), a conductive metal nitride (e.g., titanium nitride, tantalum nitride, and tungsten nitride), a metal-semiconductor compound (e.g., a metal silicide), or a combination thereof.

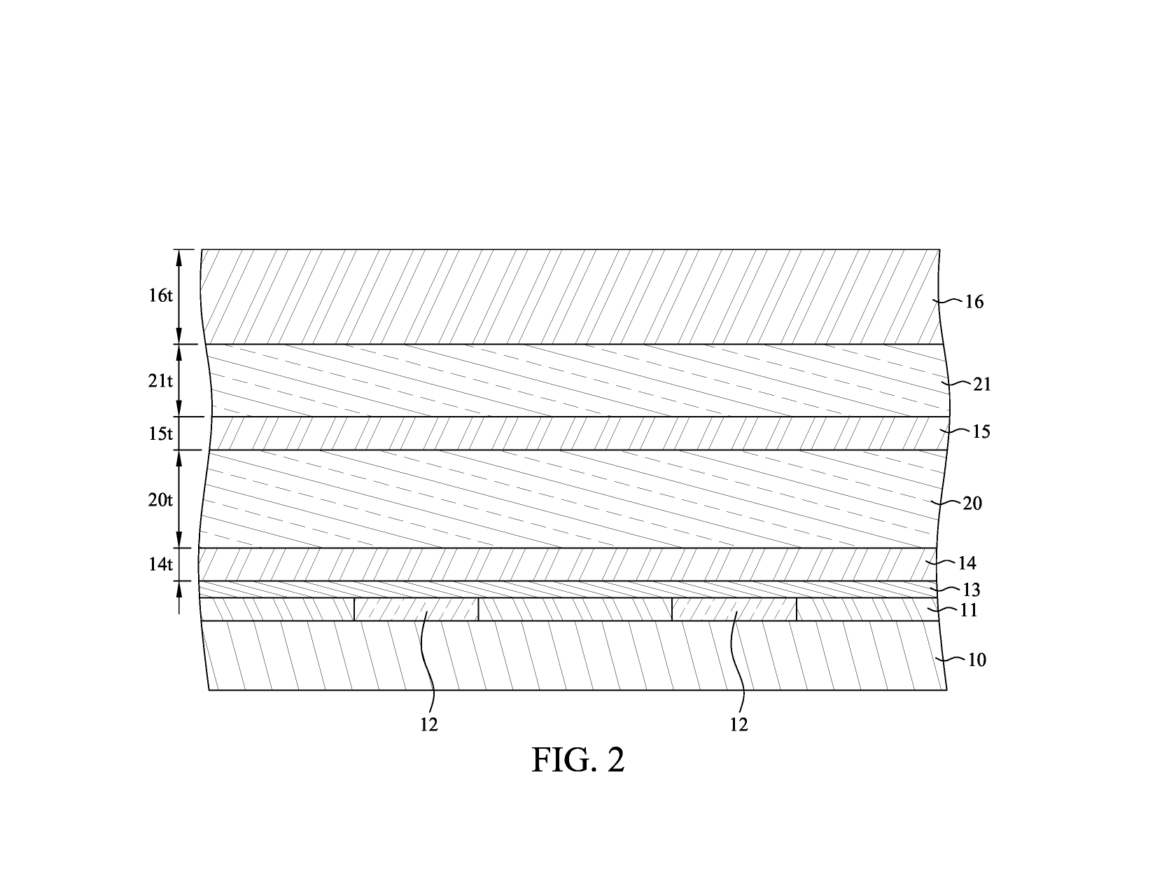

The etch stop layer 13 may be disposed on the interlayer insulating layer 11. The etch stop layer 13 may surround a portion of a sidewall of the lower electrode 17. The etch stop layer 13 may include a material having an etch selectivity with respect to the mold layer 20 and the mold layer 21 in FIG. 2. The etch stop layer 13 may include silicon nitride (SiN) or silicon oxynitride (SiON).

The support structure patterns 14, 15, and 16 may support the lower electrodes 17.

The support structure patterns 14, 15, and 16 may each have a monolithic structure in which an entire portion thereof is connected. The support structure patterns 14, 15, and 16 may each have a flat shape that is parallel to the main surface of the substrate 10 at a certain height from the main surface of the substrate 10.

The support structure patterns 14, 15, and 16 may have the same shape in a plan view. Therefore, the support structure pattern 14 and the support structure pattern 15 are covered by the support structure pattern 16 and are not shown in FIG. 1A.

The support structure pattern 16 may include or define a plurality of contact holes R1. The plurality of contact holes R1 may be arranged along a first direction (the x direction) and a second direction (the y direction), respectively. The plurality of contact holes R1 may be respectively disposed at a vertex and a center of a honeycomb-shaped hexagon. The plurality of contact holes R1 may each have a circular shape.

The support structure pattern 16 may include or define a plurality of open regions R2. The plurality of open portions R2 may be arranged along the first direction (the x direction) and the second direction (the y direction), respectively. The plurality of open portions R2 may be respectively disposed at a vertex and a center of a honeycomb-shaped hexagon. The plurality of open portions R2 may each be disposed among four contact holes R1. The plurality of open portions R2 may each be surrounded by four contact holes R1.

The plurality of open portions R2 may each have an ellipse shape or an oval shape. A dimension (such as a width or a length) X4 of the open portion R2 in the first direction (the x direction) may be less than a dimension (such as a width or a length) Y4 of the open portion R2 in the second direction (the y direction). A ratio of the dimension Y4 to the dimension X4 may be greater than 1.5. A ratio of the dimension Y4 to the dimension X4 may be substantially equal to 1.55.

The support structure patterns 14, 15, and 16 may each include silicon oxycarbide (SiOC), silicon oxynitride (SiON), silicon nitride (SiN), silicon carbon nitride (SiCN), tantalum oxide (TaO), or the like. Although three support structure patterns are illustrated, the inventive concept is not limited thereto. The number of support structure patterns may be two, four, five, or more. The support structure patterns 14, 15, and 16 may be referred to as a first support structure pattern, a second support structure pattern, and a third support structure pattern.

A thickness 14t of the support structure pattern 14 may be about 20 nanometers (nm) to 40 nm, such as 30 nm. A thickness 15t of the support structure pattern 15 may be about 20 nm to 40 nm, such as 30 nm. The thickness 14t may be substantially equal to the thickness 15t.

A thickness 16t of the support structure pattern 16 may be about 80 nm to 100 nm, such as 90 nm. The thickness 16t may be approximately three times as large as the thickness 14t. The thickness 16t may be approximately three times as large as the thickness 15t.

The lower electrodes 17 may be formed on the substrate 10. For example, the lower electrodes 17 may be formed on the contact plug 12 formed in the interlayer insulating film 11. The lower electrodes 17 may be electrically connected with the contact plug 12. The lower electrodes 17 may be formed as extending in a perpendicular direction with respect to the substrate 10.

The lower electrodes 17 may be disposed conformally along a sidewall and a bottom surface of the contact holes R1. The lower electrodes 17 may each have a cylinder shape, e.g., with a U-Shaped cross-section. In comparison with lower electrodes having pillar-type structures, the lower electrodes having cylinder-type structures may have higher capacitance and the heights can be lower. Thus, the probability of the lower electrodes 17 collapsing may be reduced.

The lower electrode 17 may include a doped semiconductor material (e.g., doped silicon), a metal (e.g., tungsten, titanium, and tantalum), a conductive metal nitride (e.g., titanium nitride, titanium aluminum nitride, titanium silicon nitride, tantalum nitride, tantalum aluminum nitride, tantalum silicon nitride, and tungsten nitride), a conductive metal oxide (e.g., iridium oxide), or other conductive materials.

The capacitor dielectric layer 18 may be conformally disposed on the etch stop layer 13, the support structure pattern 14, the support structure pattern 15, the support structure pattern 16, and the plurality of lower electrodes 17. The capacitor dielectric layer 18 may be formed of a single layer or a multi-layer.

The capacitor dielectric layer 18 may include silicon oxide (SiO2), silicon nitride (SiN), silicon oxynitride (SiON), a high-k dielectric material, or a combination thereof. For example, the high-k dielectric material may include hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or the like.

The upper electrode 19 may be disposed on the capacitor dielectric layer 18 in the contact hole R1. The upper electrode 19 may be disposed between the adjacent lower electrodes 17 in the open region R2. The upper electrode 19 may be disposed among the support structure pattern 14, the support structure pattern 15, and the support structure pattern 16. The upper electrode 19 may include a material described above for the lower electrodes 17.

As the aspect ratio of the open region R2 increases, an exposure dose required to form the open region R2 increases and the opening shape is difficult to control, potentially increasing the difficulty of forming the dielectric material of the capacitor in subsequent operations.

According to some embodiments of the present disclosure, the open regions R2 of the semiconductor device 1a are defined by a multilayer mask configured to make a ratio of the dimension Y4 to the dimension X4 greater than 1.5. Therefore, more surface area of the open region R2 is exposed, and thus subsequent operations (such as a dielectric material deposition operation and a conductive material deposition operation for forming an upper electrode) can be performed smoothly and uniformly. The capacitance of the semiconductor device 1a can be increased.

FIGS. 2, 3A, 3B, 4, 5, 6, 7, 8, 9, 10A, 10B, 11, 12, 13, 14, 15, 16, and 17 illustrate stages of a method of manufacturing a semiconductor device in accordance with some embodiments of the present disclosure. At least some of these figures have been simplified for a better understanding of the aspects of the present disclosure. In some embodiments, the semiconductor device 1a in FIG. 1A may be manufactured by the operations described below with respect to FIGS. 2, 3A, 3B, 4, 5, 6, 7, 8, 9, 10A, 10B, 11, 12, 13, 14, 15, 16, and 17.

As shown in FIG. 2A, an insulating layer may be formed over a substrate 10. The insulating layer may include an etch stop layer 13, a support structure pattern 14, a mold layer 20, a support structure pattern 15, a mold layer 21, and a support structure pattern 16 stacked over the substrate 10 in sequence.

The mold layer 20 and the mold layer 21 may each include silicon oxide (SiO₂), undoped silica glass (USG), borosilica glass (BSG), phosphosilica glass (PSG), borophosphosilica glass (BPSG), tetraethyl orthosilicate (TEOS), plasma enhanced tetraethyl orthosilicate (PE-TEOS), and fluoride silicate glass (FSG), etc. The insulating layer may be formed by any suitable process, such as chemical vapor deposition (CVD) or physical vapor deposition (PVD).

A thickness 20t of the mold layer 20 may be about 530 nm to 570 nm, such as 540 nm, 550 nm, or 560 nm. A thickness 21t of the mold layer 21 may be about 380 nm to 420 nm, such as 390 nm, 400 nm, or 410 nm. The mold layer 20 and the mold layer 21 may be referred to as a first mold layer and a second mold layer.

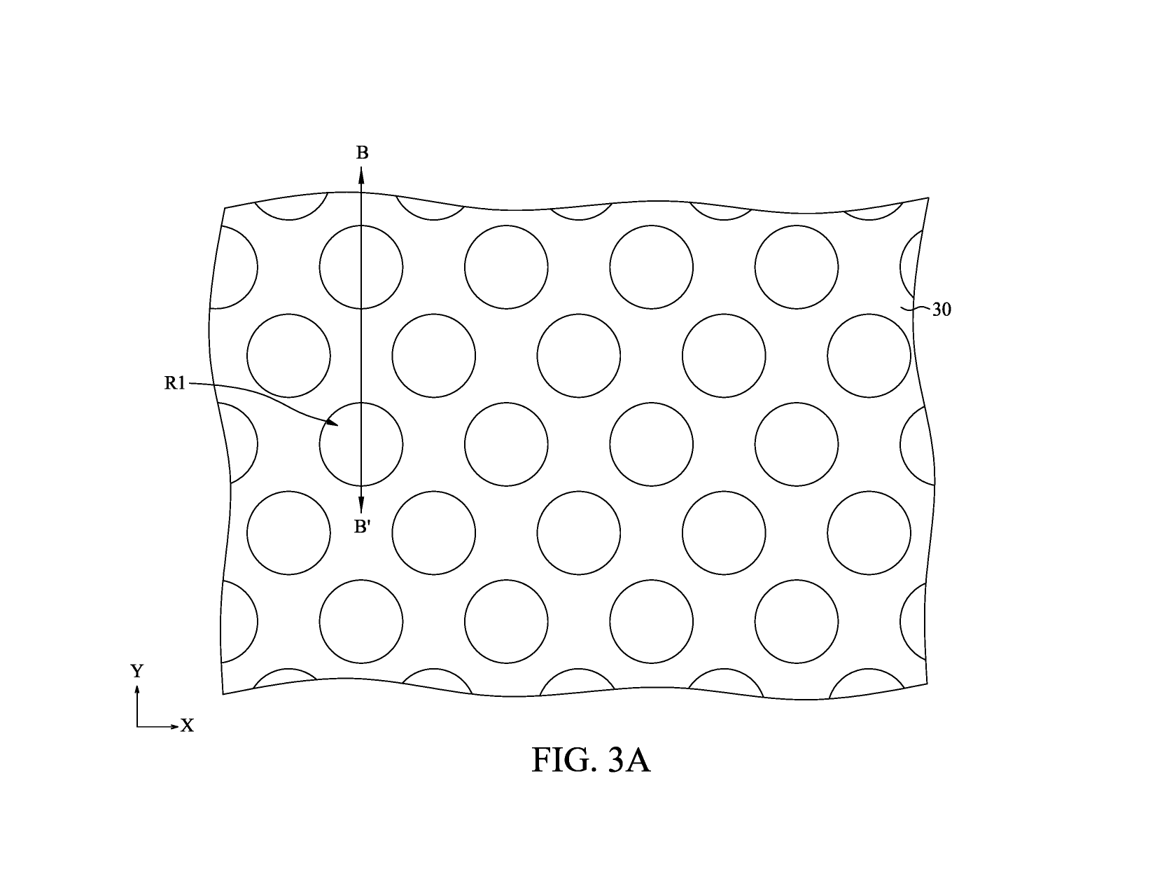

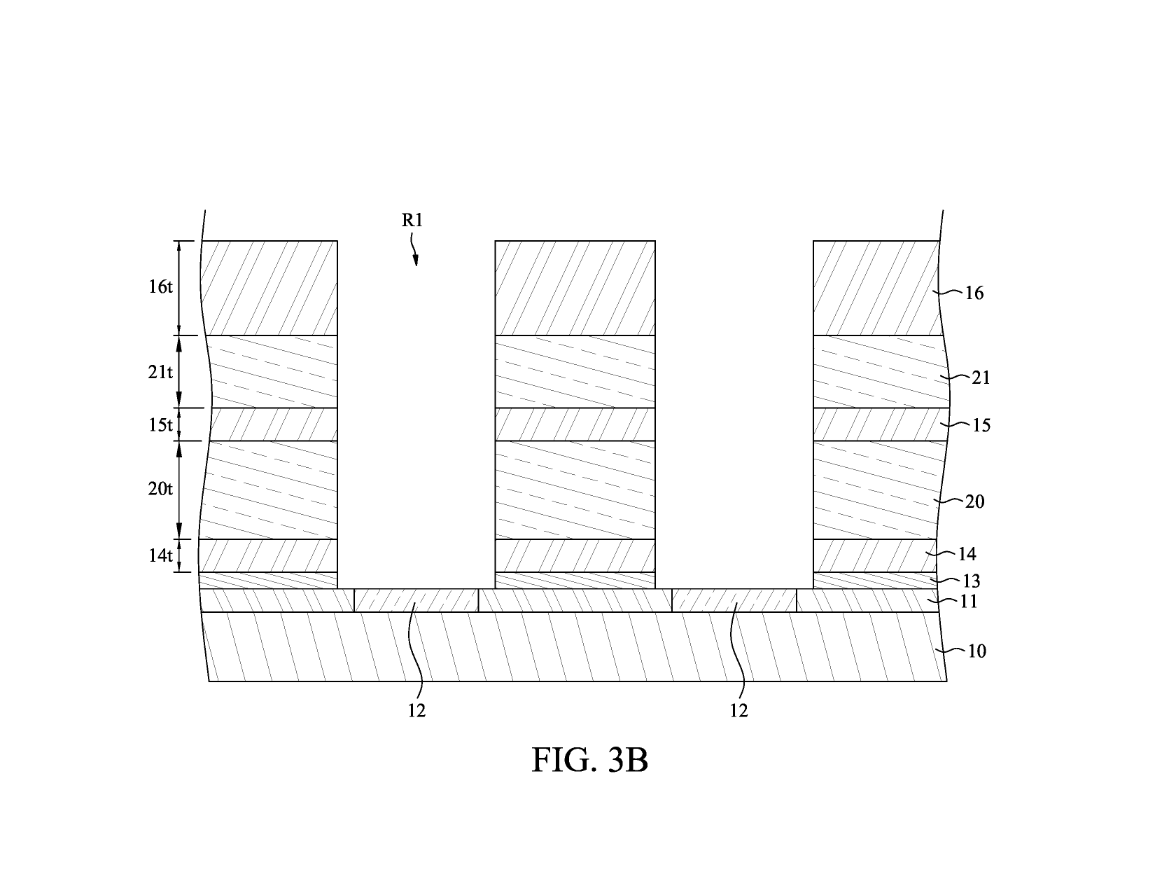

As shown in FIG. 3A, a mask pattern 30 may be formed on the support structure pattern 16. The mask pattern 30 may include or define a plurality of contact holes R1. The contact holes R1 may be circular and may have honeycomb structures in which the contact holes R1 are arranged at vertices and a central point of a honeycomb-shaped hexagon.

FIG. 3B is a schematic cross-sectional view illustrating the semiconductor device taken along a B-B’ line shown in FIG. 3A.

The insulating layer may be partially etched by using a suitable etching operation, such as a directional or anisotropic dry etching operation. After the etching operation, a plurality of contact holes R1 are formed in the insulating layer. The mask pattern 30 may be removed.

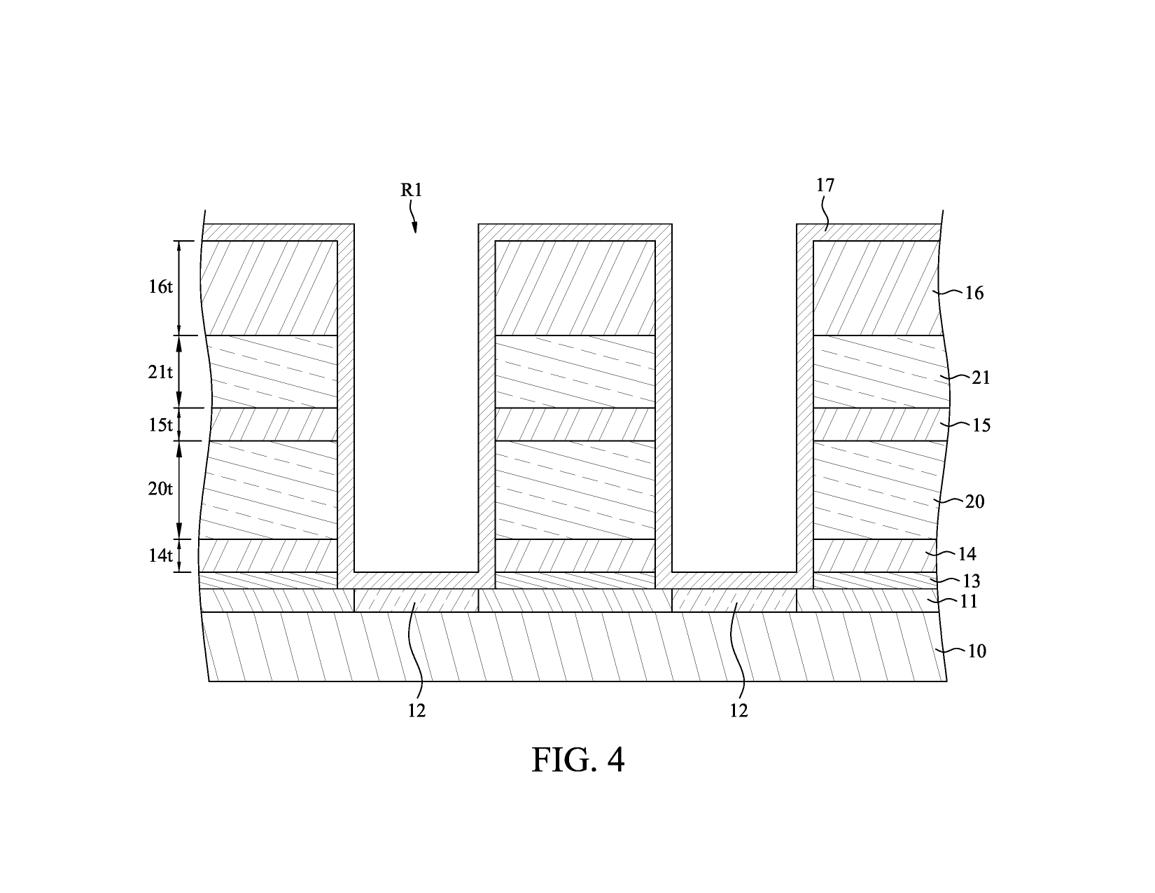

As shown in FIG. 4, a plurality of lower electrodes 17 may be disposed in the contact holes R1. For example, the plurality of lower electrodes 17 may be disposed on the upper surface of the contact plugs 12 exposed by the contact holes R1, on the inner surfaces or walls of the contact holes R1, and on the top surface of the insulating layer. The plurality of lower electrodes 17 may be formed by any suitable process, such as chemical vapor deposition (CVD) or physical vapor deposition (PVD).

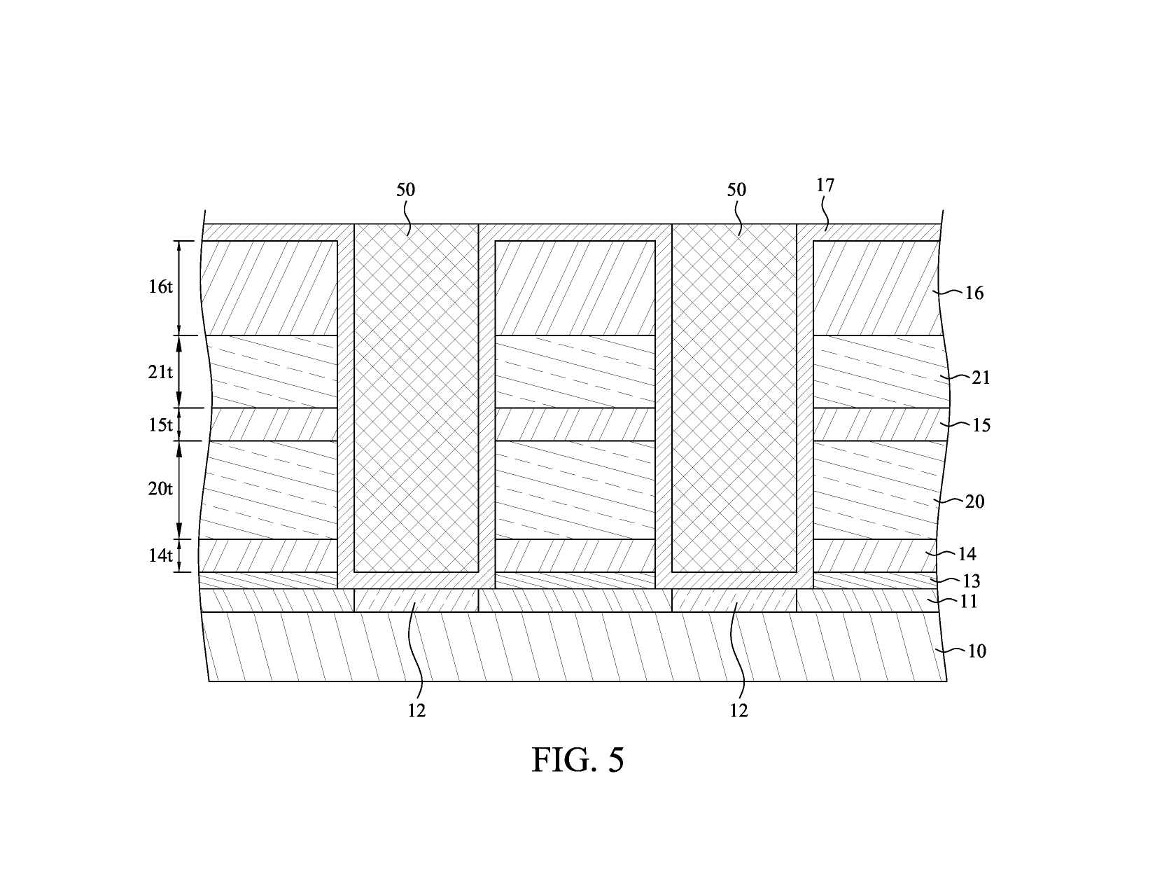

As shown in FIG. 5, a sacrificial film 50 may be formed on the lower electrode 17 to fill the contact hole R1. The sacrificial film 50 may include an oxide such as undoped silica glass (USG), spin on glass (SOG), or the like. The sacrificial film 50 may include a material having excellent gap-filling capability. The sacrificial film 50 may be configured to protect the lower electrode 17 during a polishing process and an etching process.

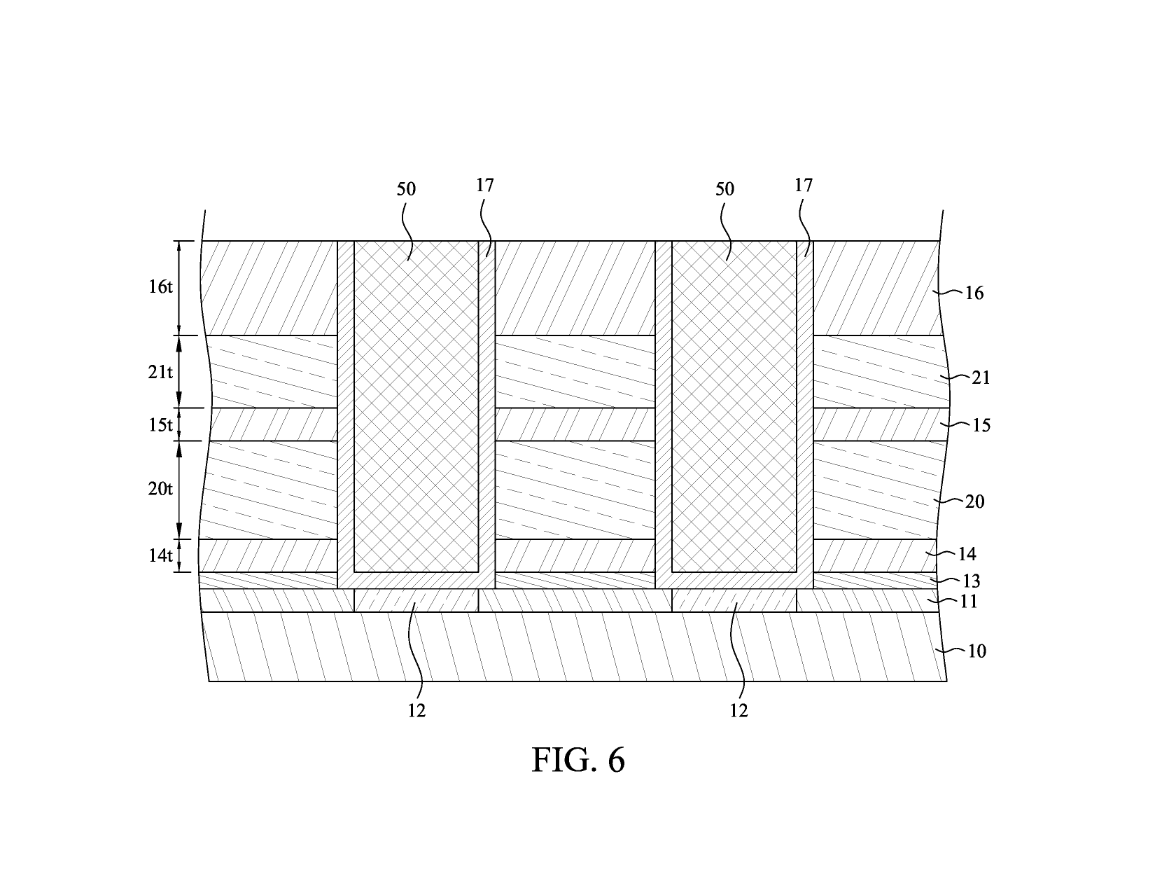

As shown in FIG. 6, the sacrificial film 50 and the lower electrode 17 are partially removed through a chemical mechanical polishing (CMP) operation and an etch back operation. The support structure pattern 16 may be exposed.

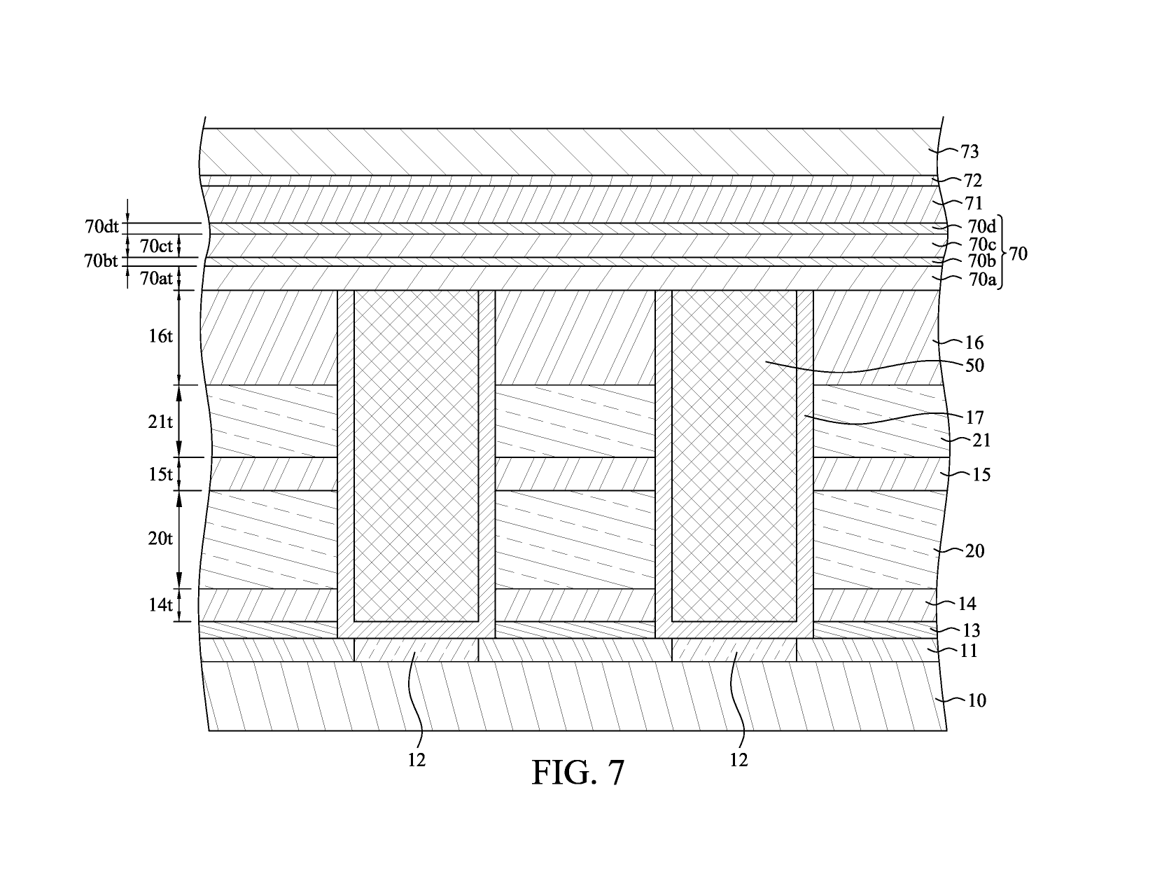

As shown in FIG. 7, a multilayer mask 70 may be disposed on the insulating layer. A dielectric antireflective coating (DARC) 71, a bottom layer antireflective coating (BARC) 72, and a photoresist 73 may be disposed on the multilayer mask 70. A thickness of the multilayer mask 70 may be about 22 nm to 38 nm, such as 23 nm, 24 nm, 25 nm, 26 nm, 27 nm, 28 nm, 29 nm, 30 nm, etc.

The multilayer mask 70 may include a carbon and an oxide. The multilayer mask 70 may include a carbon-containing layer 70a (which may be referred to as a first carbon-containing layer), an oxide-containing layer 70b (which may be referred to as a first oxide-containing layer), a carbon-containing layer 70c (which may be referred to as a second carbon-containing layer), and an oxide-containing layer 70d (which may be referred to as a second oxide-containing layer).

In some embodiments, the carbon-containing layers 70a and 70c may include a carbon-containing material, such as SiC (silicon carbide), SiOC (silicon oxycarbide), SiCN (silicon carbon nitride), and SiOCN (silicon oxycarbonitride). The oxide-containing layers 70b and 70d may include an oxide-containing material, such as silicon oxide (SiO₂).

In some embodiments, the thickness 70at of the carbon-containing layer 70a may be about 8 nm to 12 nm, such as 9 nm, 10 nm, or 11 nm. The thickness 70ct of the carbon-containing layer 70c may be about 8 nm to 12 nm, such as 9 nm, 10 nm, or 11 nm. In some embodiments, the thickness 70at of the carbon-containing layer 70a may be substantially equal to the thickness 70ct of the carbon-containing layer 70c.

In some embodiments, the thickness 70bt of the oxide-containing layers 70b may be about 3 nm to 7 nm, such as 4 nm, 5 nm, or 6 nm. The thickness 70dt of the oxide-containing layers 70d may be about 3 nm to 7 nm, such as 4 nm, 5 nm, or 6 nm. In some embodiments, the thickness 70bt of the oxide-containing layers 70b may be substantially equal to the thickness 70dt of the oxide-containing layers 70d.

In some embodiments, the thickness 70at of the carbon-containing layer 70a may be approximately twice as large as the thickness 70bt of the oxide-containing layers 70b. In some embodiments, the thickness 70ct of the carbon-containing layer 70c may be approximately twice as large as the thickness 70dt of the oxide-containing layers 70d.

In some embodiments, the carbon-containing layers 70a and 70c may be formed by any suitable process, such as low-pressure chemical vapor deposition (LPCVD), plasma enhanced-chemical vapor deposition (PECVD), atomic layer deposition (ALD), or physical vapor deposition (PVD), thermally grown, or chemically grown. In some embodiments, the oxide-containing layers 70b and 70d may formed by any suitable process, such as atomic layer deposition (ALD).

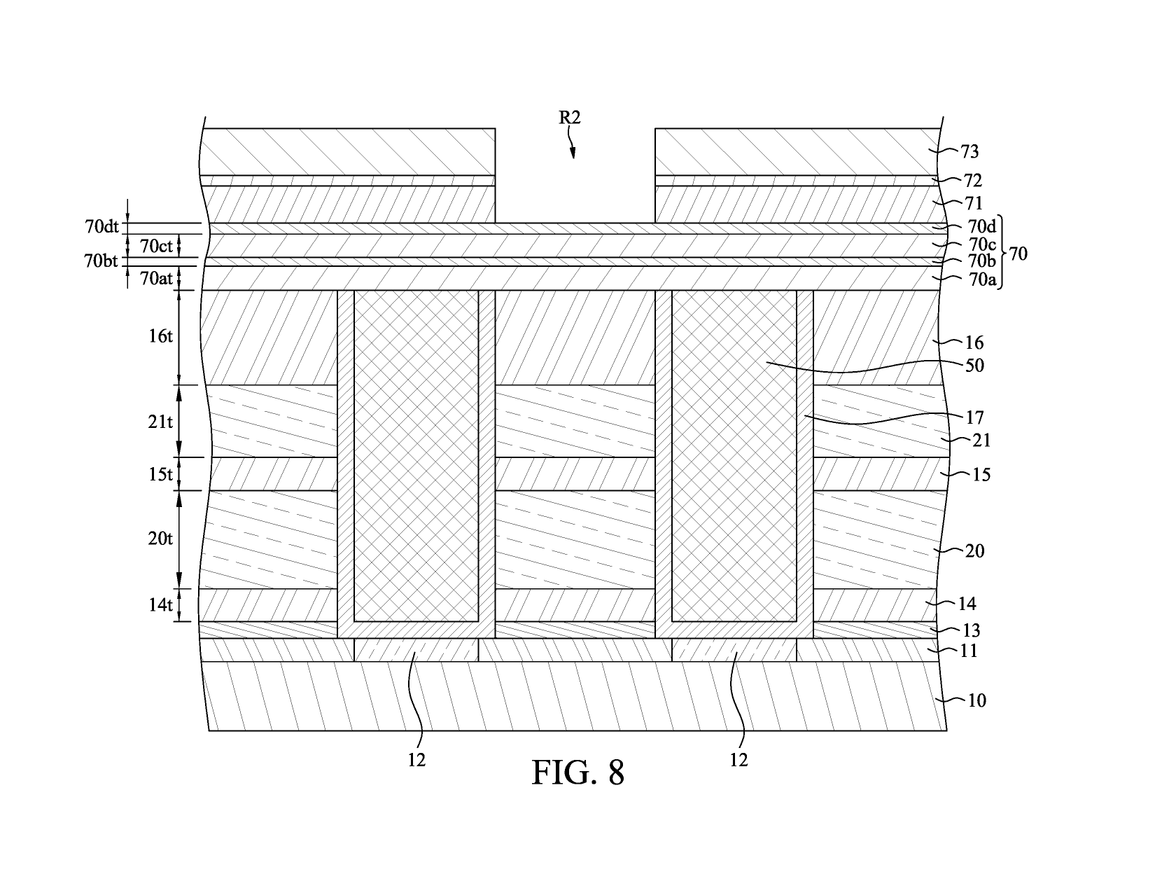

As shown in FIG. 8, an open region R2 may be defined by the photoresist 73 and a portion of the multilayer mask 70 may be exposed.

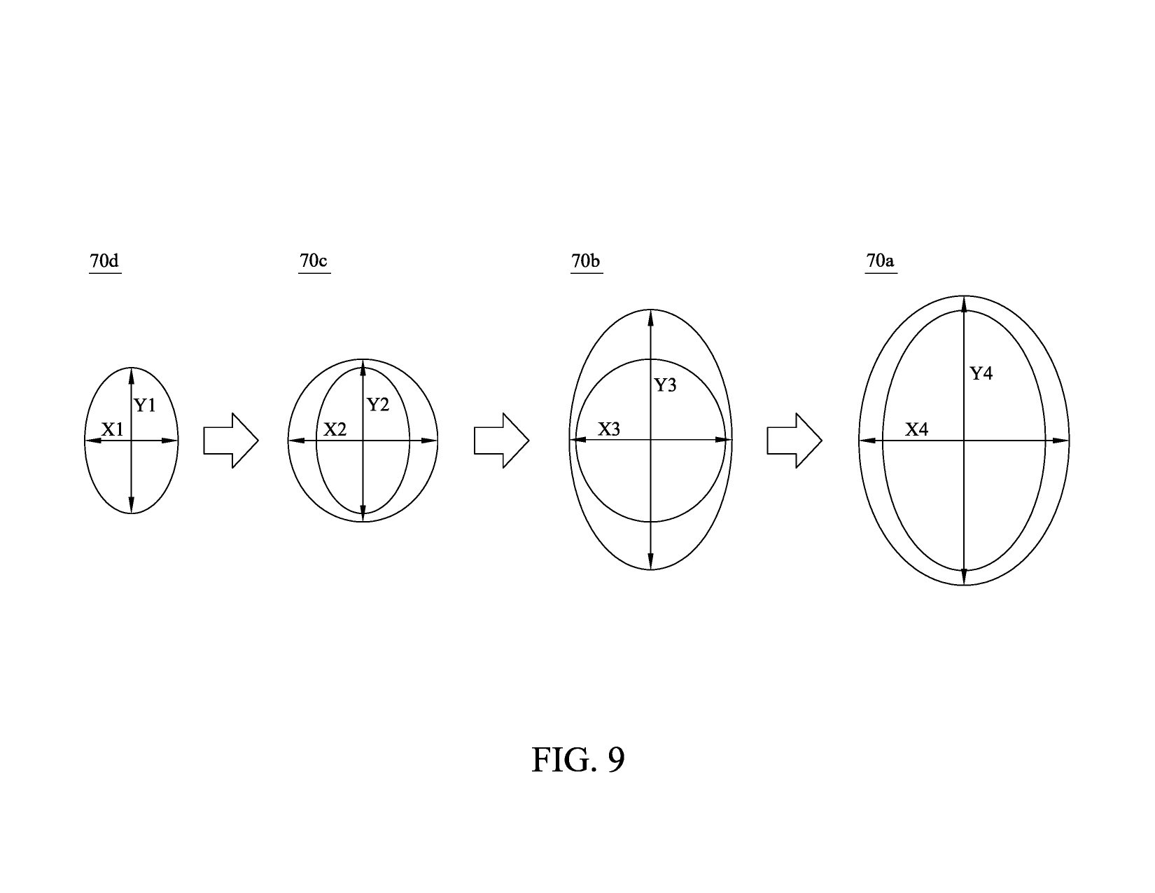

A top view of the top surface of the multilayer mask 70 as the etch progresses is shown in FIG. 9.

The oxide-containing layer 70d may be etched first. Since an etching rate in the second direction (the y direction) is greater than an etching rate in the first direction (the x direction) for the oxide-containing layer 70d, a dimension (such as a width or a length) Y1 of the oxide-containing layer 70d may be greater than a dimension (such as a width or a length) X1 of the oxide-containing layer 70d.

Then, the carbon-containing layer 70c may be etched. Unlike the oxide-containing layer 70d, the carbon-containing layer 70c may be etched isotropically. Therefore, a ratio of the dimension Y2 to the dimension X2 may be less than a ratio of the dimension Y1 to the dimension X1, making it difficult to maintain the ideal shape of the open region R2.

However, since the carbon-containing layer 70c may have an etch selectivity with respect to the support structure patterns 14, 15, and 16, the carbon-containing layer 70c may decrease the thickness of the multilayer mask 70 and the aspect ratio of the open region R2.

Then, the oxide-containing layer 70b may be etched. A ratio of the dimension Y3 to the dimension X3 may be greater than a ratio of the dimension Y2 to the dimension X2.

Finally, the carbon-containing layer 70a may be etched.

As shown in 10A, a ratio of the dimension Y4 to the dimension X4 may be greater than 1.5. A ratio of the dimension Y4 to the dimension X4 may be substantially equal to 1.55.

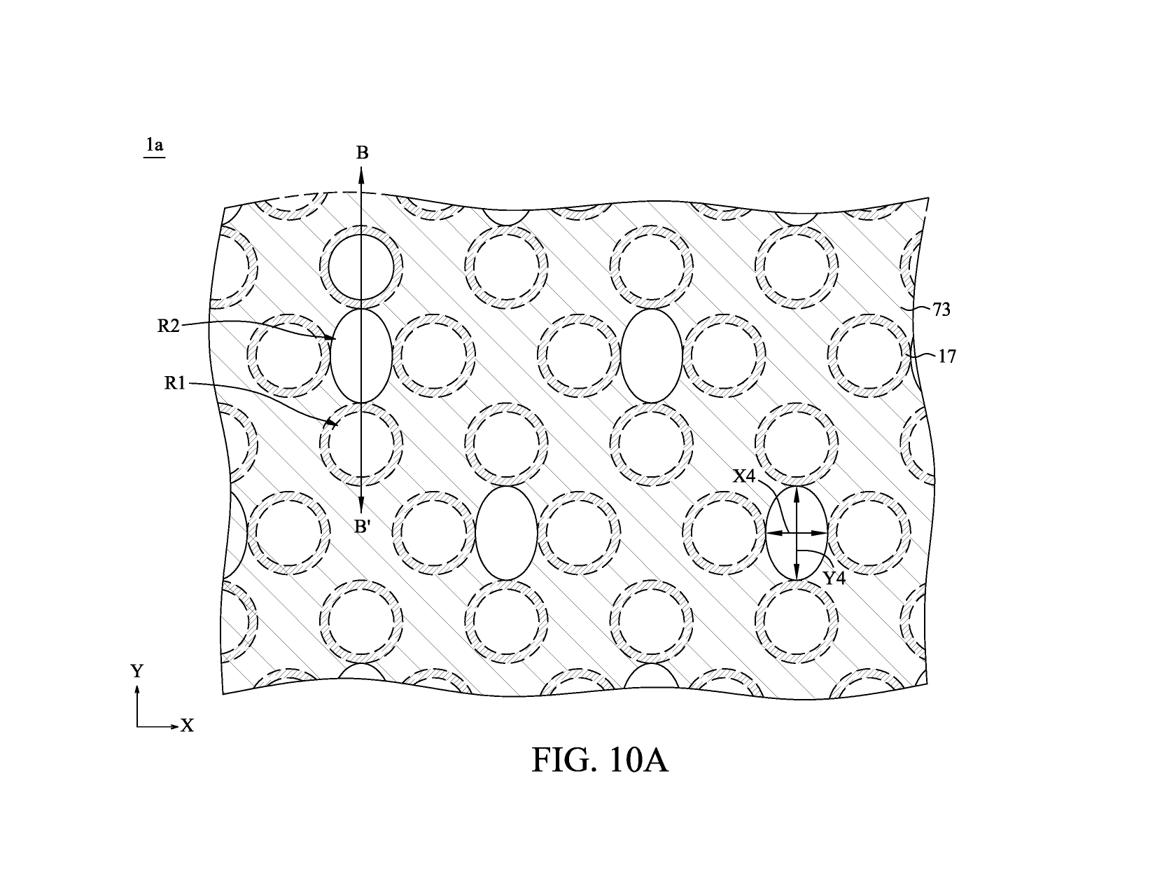

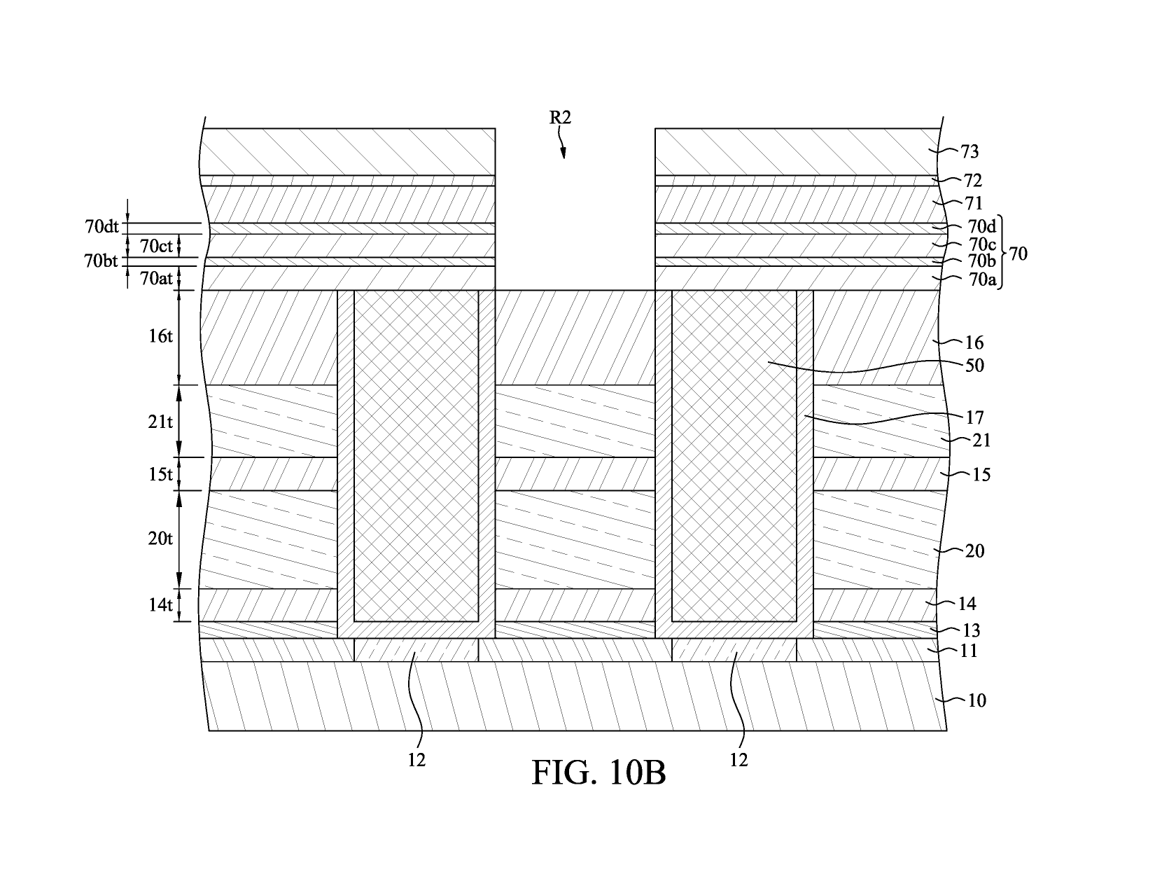

FIG. 10B is a schematic cross-sectional view illustrating the semiconductor device taken along a B-B’ line shown in FIG. 10A. The support structure pattern 16 is exposed from the open region R2.

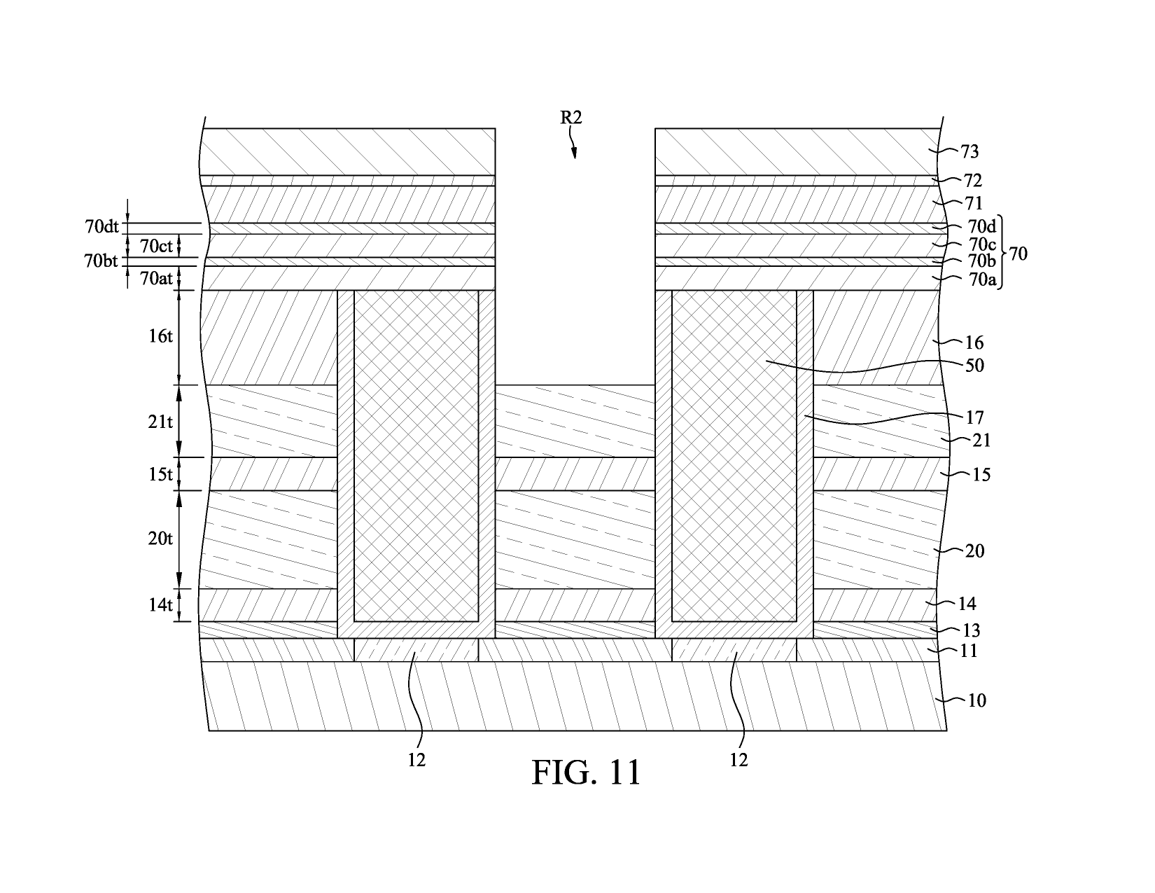

As shown in FIG. 11, the support structure pattern 16 may be etched by using the multilayer mask 70 as an etch mask. A plasma etching operation can be performed. For example, a fluorocarbon (CxFy)-based etch gas or a hydrofluorocarbon (CxHyFz)-based etch gas may be used. For example, sulfur dioxide (SO₂) gas and octafluorocyclobutane (C₄F₈) gas can be used.

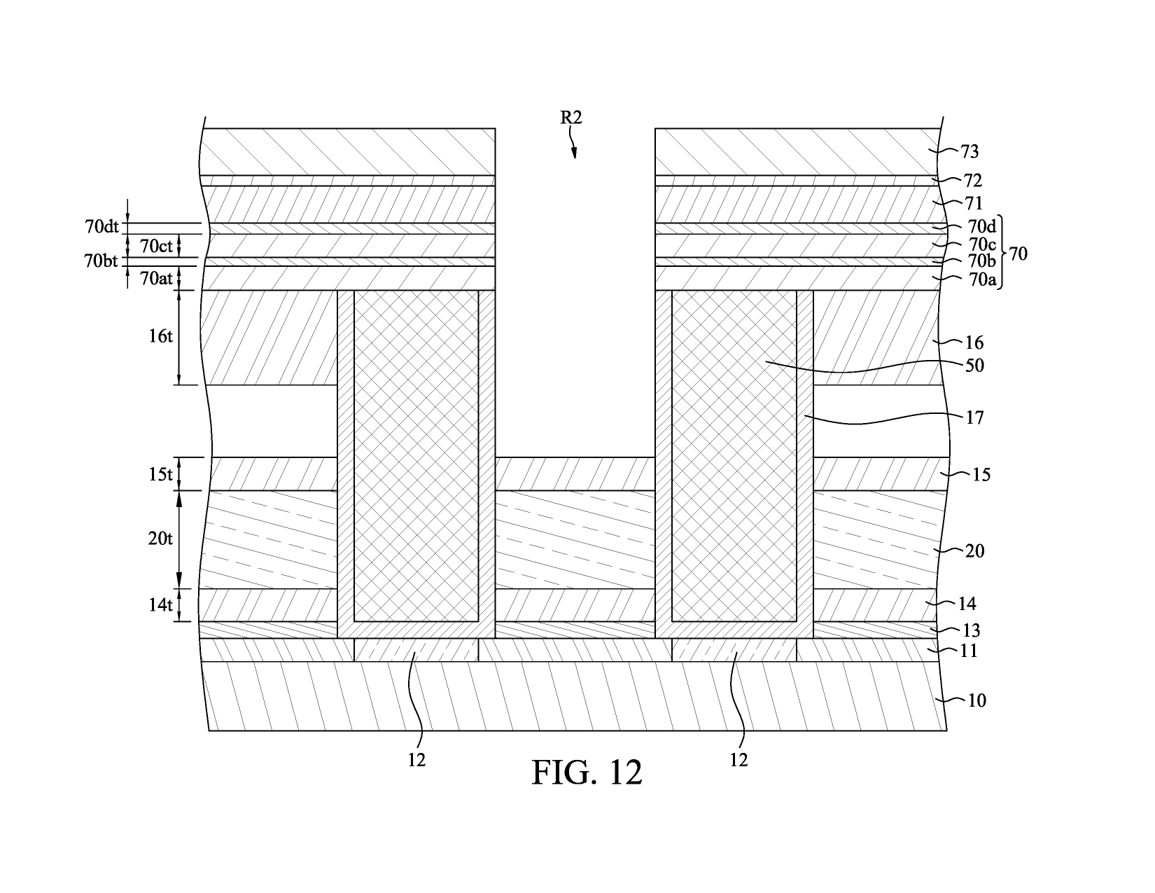

As shown in FIG. 12, the mold layer 21 may be etched. A wet etching operation may be performed by using a wet etchant. The wet etchant may contact the mold layer 21 through the opening of the support structure pattern 15, and the mold layer 21 may be removed by the wet etchant.

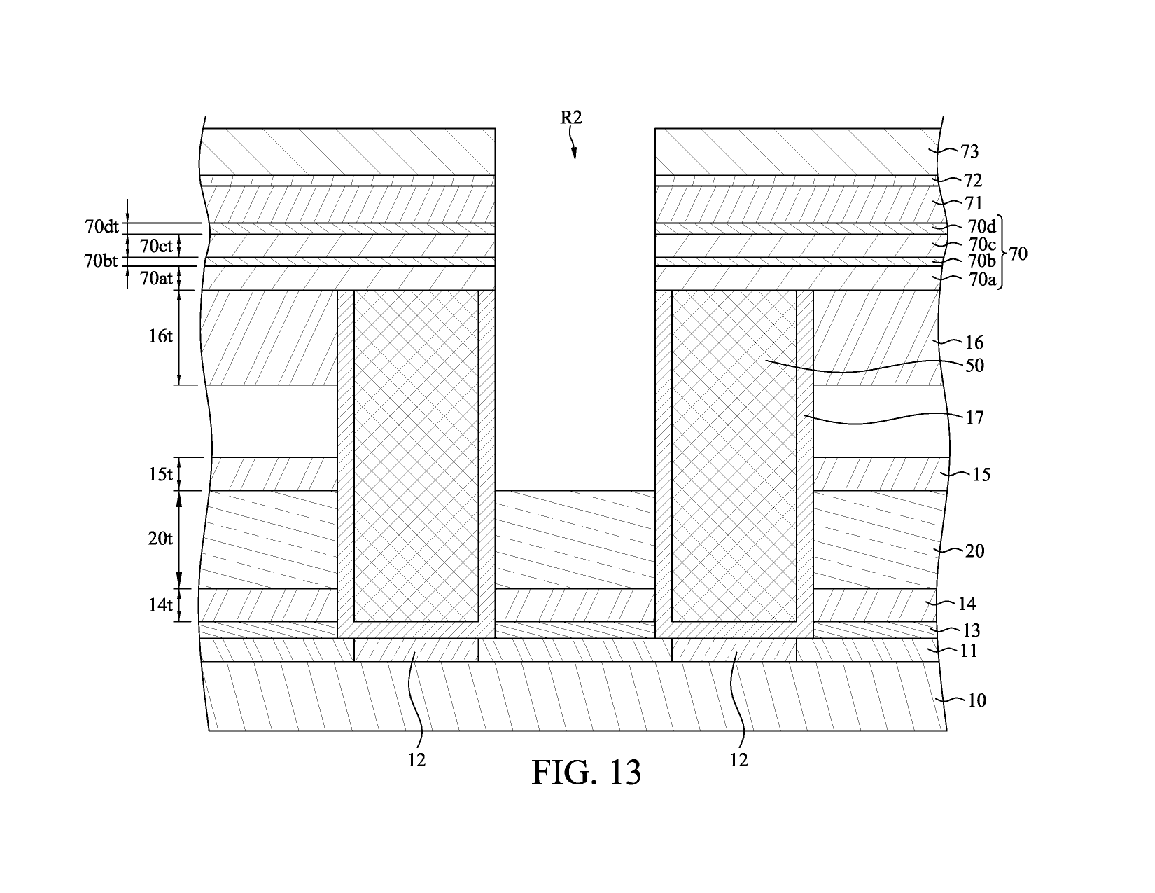

As shown in FIG. 13, the support structure pattern 15 may be etched by using the multilayer mask 70 as an etch mask. A plasma etching operation can be performed.

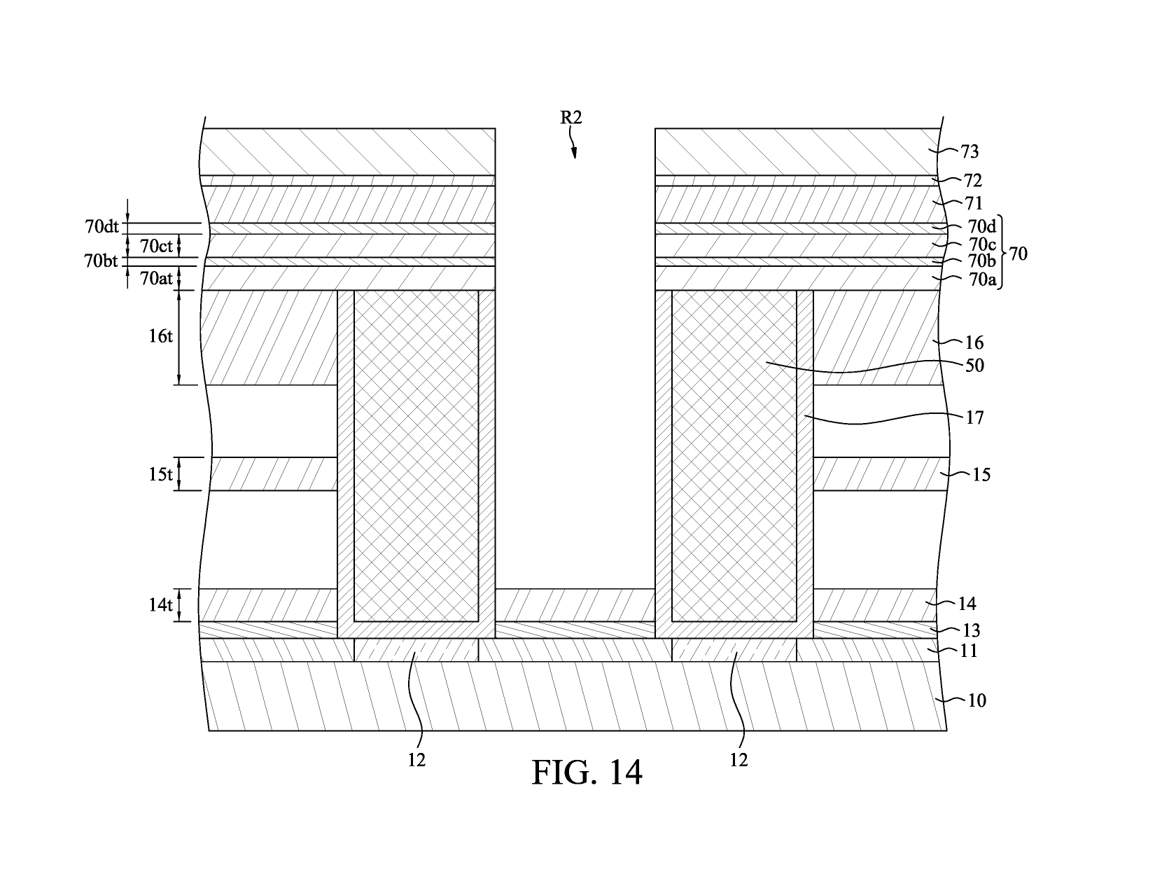

As shown in FIG. 14, the mold layer 20 may be etched. A wet etching operation may be performed by using a wet etchant.

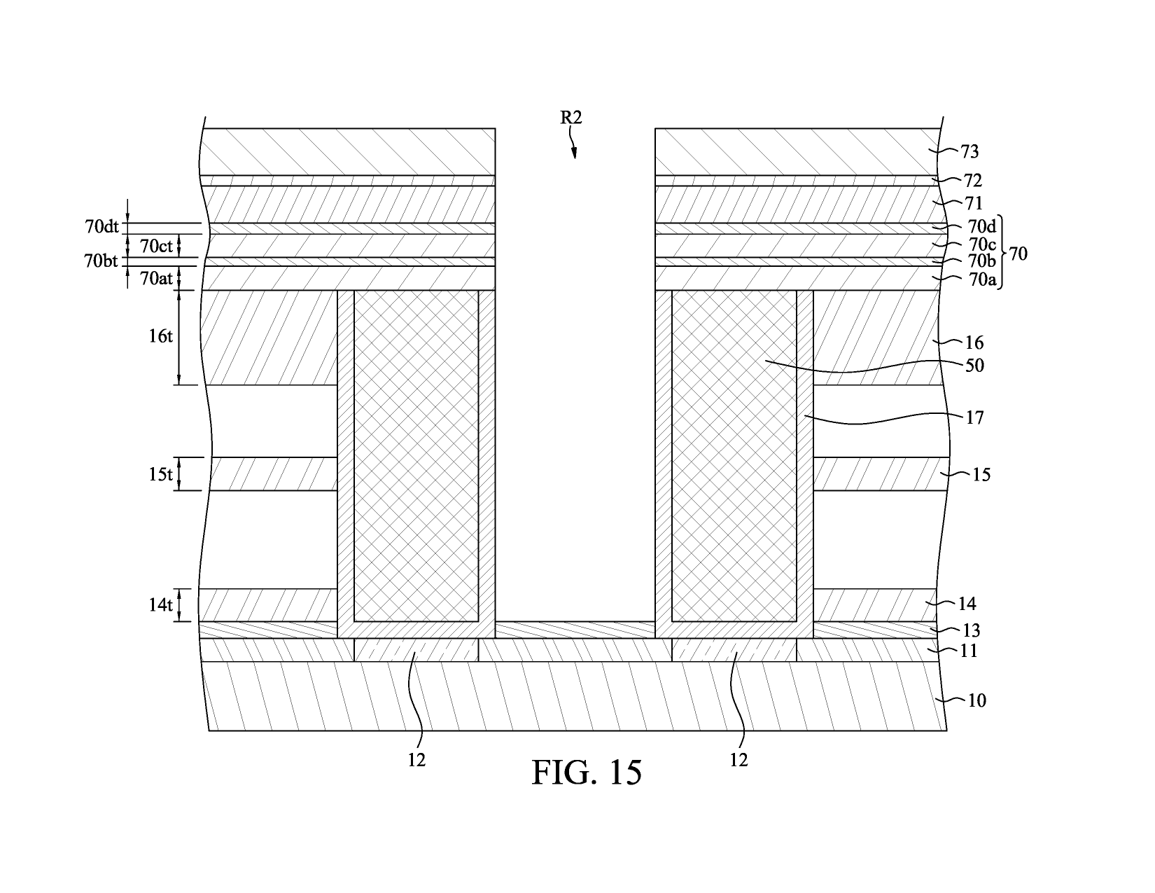

As shown in FIG. 15, the support structure pattern 14 may be etched by using the multilayer mask 70 as an etch mask. A plasma etching operation can be performed.

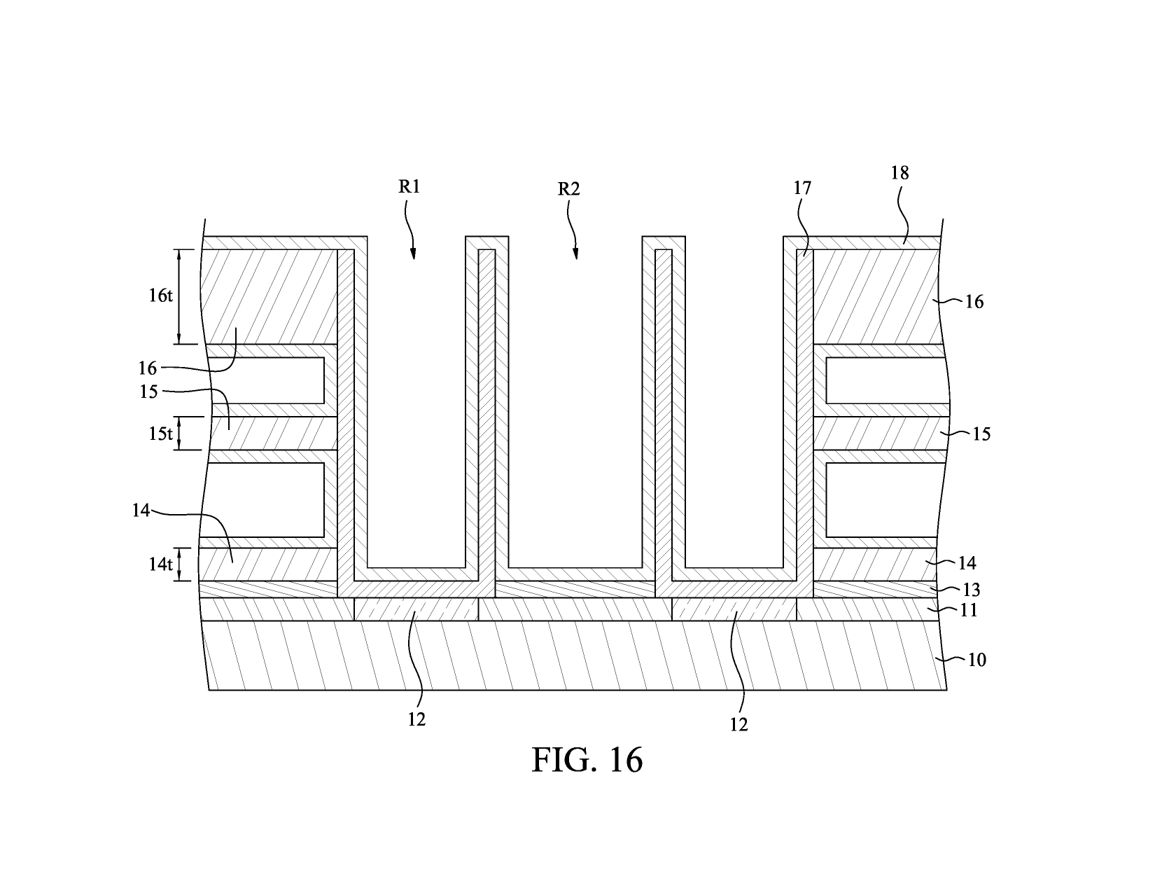

As shown in FIG. 16, the sacrificial film 50, the DARC 71, the BARC 72, the photoresist 73, and the multilayer mask 70 may be removed. The capacitor dielectric layer 18 may be formed on an outer wall and an inner wall of the lower electrode 17. The capacitor dielectric layer 18 may be formed on the support structure patterns 14, 15, and 16. The capacitor dielectric layer 18 may be formed by any suitable process, such as atomic layer deposition (ALD) or physical vapor deposition (PVD).

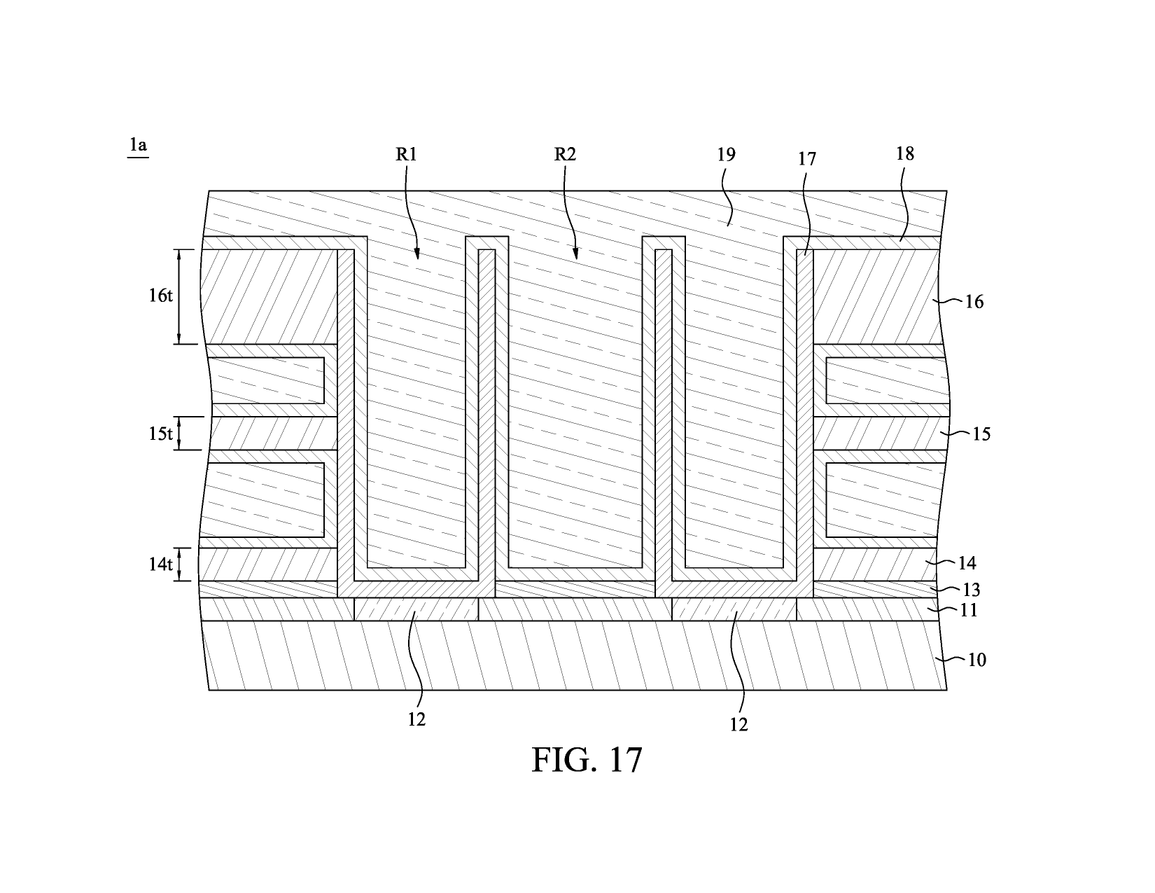

As shown in FIG. 17, the upper electrode 19 may be disposed in the contact hole R1 and the open region R2. After the upper electrode 19 is formed, a plasma treatment operation or a heat treatment operation for removing impurities generated during the deposition of the upper electrode 19 may be performed.

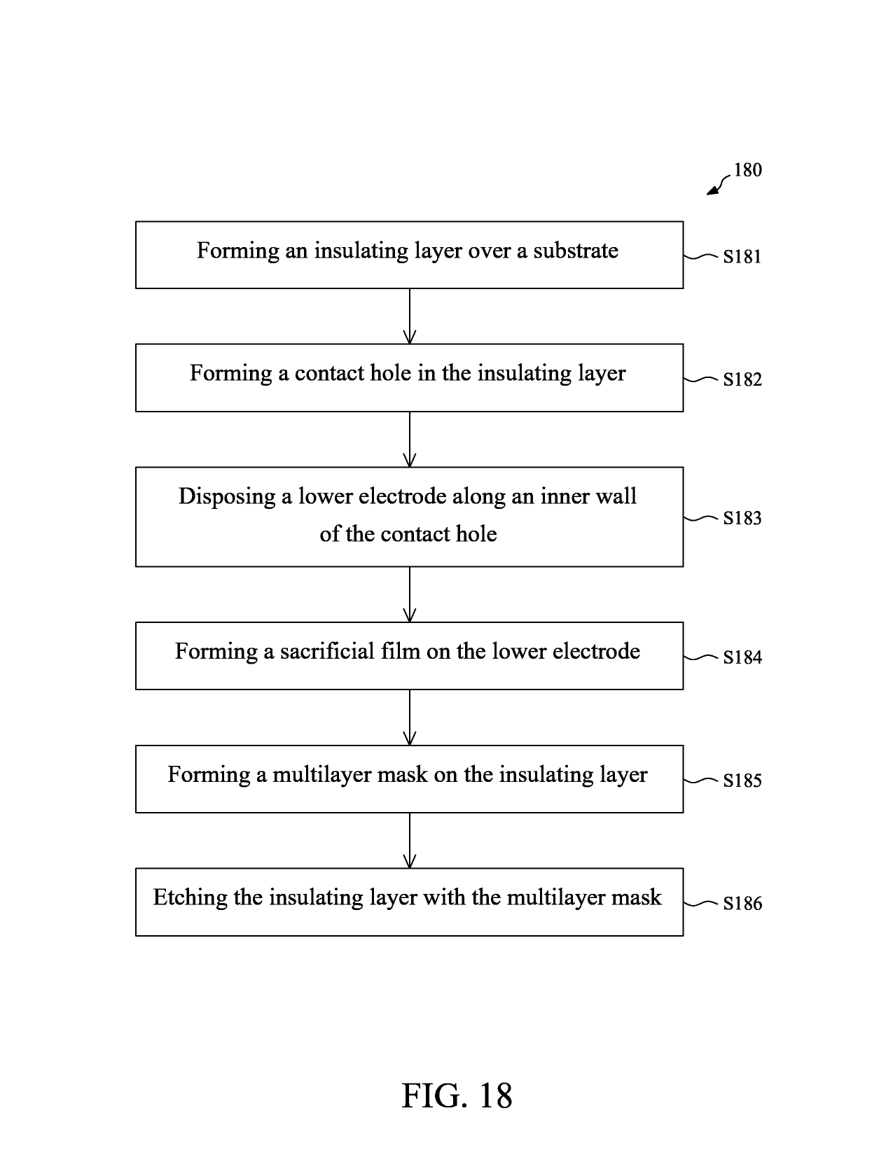

FIG. 18 illustrates a flow chart of a method 180 of manufacturing a semiconductor device in accordance with some embodiments of the present disclosure.

In some embodiments, the method 180 may include a step S181 of forming an insulating layer over a substrate. For example, as shown in FIG. 2, an insulating layer may be formed over a substrate 10. The insulating layer may include an etch stop layer 13, a support structure pattern 14, a mold layer 20, a support structure pattern 15, a mold layer 21, and a support structure pattern 16 stacked over the substrate 10 in sequence.

In some embodiments, the method 180 may include a step S182 of forming a contact hole in the insulating layer. For example, as shown in FIG. 3B, a plurality of contact holes R1 are formed in the insulating layer.

In some embodiments, the method 180 may include a step S183 of disposing a lower electrode along an inner wall of the contact hole. For example, as shown in FIG. 4, a plurality of lower electrodes 17 may be disposed in the contact holes R1.

In some embodiments, the method 180 may include a step S184 of forming a sacrificial film on the lower electrode. For example, as shown in FIG. 5, a sacrificial film 50 may be formed on the lower electrode 17 to fill the contact hole R1.

In some embodiments, the method 180 may include a step S185 of forming a multilayer mask on the insulating layer. For example, as shown in FIG. 7, a multilayer mask 70 may be disposed on the insulating layer.

In some embodiments, the method 180 may include a step S186 of etching the insulating layer with the multilayer mask. For example, as shown in FIG. 11, the support structure pattern 16 is exposed from the open region R2 and etched by using the multilayer mask 70 as an etch mask.

One aspect of the present disclosure provides a semiconductor device. The semiconductor device includes a substrate, a plurality of lower electrodes disposed on the substrate, and at least one support structure pattern supporting the plurality of lower electrodes. The at least one support structure pattern define an open region having a first dimension along a first direction and a second dimension along a second direction. A ratio of the second dimension to the first dimension is greater than 1.5.

Another aspect of the present disclosure provides a method of manufacturing a semiconductor device. The method includes forming an insulating layer on a substrate, forming a plurality of lower electrodes in the insulating layer; forming a multilayer mask on the insulating layer, and etching the insulating layer with the multilayer mask.

Another aspect of the present disclosure provides a method of manufacturing a semiconductor device. The method includes forming a plurality of lower electrodes, forming a support structure pattern supporting the plurality of lower electrodes, forming a multilayer mask on the support structure pattern, and forming an open region having an ellipse shape with the multilayer mask.

By using a multilayer mask to form the open region, a ratio of the major axis to the minor axis of the elliptical shape of the open region can be greater than 1.5. The capacitor dielectric layer may be completely formed in the open region. Therefore, the performance and operational reliability of the semiconductor device can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a semiconductor device, comprising:
forming an insulating layer on a substrate;
forming a plurality of lower electrodes in the insulating layer;
forming a multilayer mask on the insulating layer; and
etching the insulating layer with the multilayer mask.

2. The method of claim 1, wherein the insulating layer includes at least one support structure pattern and at least one mold layer.

3. The method of claim 2, wherein the at least one support structure pattern includes a first support structure pattern, a second support structure pattern, and a third support structure pattern disposed at different heights from the substrate.

4. The method of claim 3, wherein a thickness of the third support structure pattern is three times as large as a thickness of the first support structure pattern.

5. The method of claim 1, wherein forming the plurality of lower electrodes in the insulating layer includes:
forming a plurality of contact holes in the insulating layer.

6. The method of claim 5, wherein forming the plurality of lower electrodes in the insulating layer further includes:
disposing the plurality of lower electrodes along inner surfaces of the plurality of contact holes.

7. The method of claim 6, wherein forming the plurality of lower electrodes in the insulating layer further includes:
forming sacrificial films on the plurality of lower electrodes in the plurality of contact holes.

8. The method of claim 1, wherein a thickness of the multilayer mask is about 30 nanometers.

9. The method of claim 1, wherein the multilayer mask includes a carbon-containing layer and an oxide-containing layer.

10. The method of claim 9, wherein a thickness of the carbon-containing layer is twice as large as a thickness of the oxide-containing layer.
